(19) United States
(12) Patent Application Publication
(10) Pub. No.: US 2025/0081467 A1
(43) Pub. Date: Mar. 6, 2025

(54) SEMICONDUCTOR DEVICE AND MANUFACTURING METHOD OF THE SAME, AND ELECTRONIC SYSTEM INCLUDING SEMICONDUCTOR DEVICE

(71) Applicant: Samsung Electronics Co., Ltd., Suwon-si (KR)

(72) Inventors: DONGJIN LEE, Suwon-si (KR); JAEDUK LEE, Suwon-si (KR); HAKSEON KIM, Suwon-si (KR); NAKJIN SON, Suwon-si (KR); KANG-OH YUN, Suwon-si (KR)

(21) Appl. No.: 18/809,742

(22) Filed: Aug. 20, 2024

(30) Foreign Application Priority Data
Aug. 28, 2023 (KR) 10-2023-0112708

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device according to an embodiment includes a semiconductor substrate, a plurality of transistors, a plurality of isolation portions, and a recess insulator. The semiconductor substrate includes a first transistor region and a second transistor region. The plurality of transistors includes a first transistor in the first transistor region and a second transistor in the second transistor region having larger operating voltage than the first transistor. Each isolation portion is at a boundary of a respective transistor of the plurality of transistors at a first surface of the semiconductor substrate. The recess insulator is disposed in the second transistor region at a second surface of the semiconductor substrate opposite to the first surface of the semiconductor substrate.

### CROSS-REFERENCE TO RELATED APPLICATION

This application claims priority under 35 USC 119(a) to and the benefit of Korean Patent Application No. 10-2023-0112708 filed in the Korean Intellectual Property Office on Aug. 28, 2023, the entire contents of which are incorporated herein by reference.

### BACKGROUND

### (a) Field

The present disclosure relates to a semiconductor device and a manufacturing method of the same, and an electronic system including a semiconductor device.

### (b) Description of the Related Art

A semiconductor device may have a small size while performing various functions and is thus widely used in various electronic industries. As advancements are made in the electronic industry, research on improving performance and integration of a semiconductor device has continued. For example, when electrical separation or isolation of a plurality of circuit elements included in a semiconductor device is improved, a distance between the plurality of circuit elements may be reduced and thus integration of the semiconductor device may be improved.

### SUMMARY

The present disclosure is directed to a semiconductor device capable of improved performance and integration, and a manufacturing method of making the same, and an electronic system including the semiconductor device.

A semiconductor device according to an embodiment includes a semiconductor substrate, a plurality of transistors, an isolation portion, and a recess insulator. The semiconductor substrate includes a first transistor region and a second transistor region. The plurality of transistors includes a first transistor in the first transistor region and a second transistor in the second transistor region having a larger operating voltage than the first transistor. Each isolation portion is at a boundary of a respective transistor of the plurality of transistors at a first surface of the semiconductor substrate. The recess insulator is disposed in the second transistor region at a second surface of the semiconductor substrate opposite to the first surface of the semiconductor substrate.

An electronic system according to an embodiment includes a main substrate, the semiconductor device on the main substrate, and a controller electrically connected to the semiconductor device on the main substrate. The semiconductor device includes a semiconductor substrate, a plurality of transistors, an isolation portion, and a recess insulator. The semiconductor substrate includes a first transistor region and a second transistor region. The plurality of transistors includes a first transistor in the first transistor region and a second transistor in the second transistor region having a larger operating voltage than the first transistor. Each isolation portion is at a boundary of a respective transistor of the plurality of transistors at a first surface of the semiconductor substrate. The recess insulator is disposed in the second transistor region at a second surface of the semiconductor substrate opposite to the first surface of the semiconductor substrate.

A method of manufacturing a semiconductor device according to an embodiment includes forming an isolation portion at a first surface of a semiconductor substrate including a first transistor region and a second transistor region, forming a first transistor in the first transistor region and a second transistor in the second transistor region, respectively, and forming a recess insulator in the second transistor region at a second surface of the semiconductor substrate opposite to the first surface of the semiconductor substrate.

According to the embodiment, a thickness of a semiconductor substrate in a region where a high-voltage transistor is positioned may be reduced by a recess insulator. The high-voltage transistor may be stably separated or insulated from another portion by a separation insulator and the recess insulator. The performance and integration of a semiconductor device including the high-voltage transistor may be improved.

### BRIEF DESCRIPTION OF THE DRAWINGS

FIG. 1 is a cross-sectional view schematically illustrating a semiconductor device according to an embodiment.

FIG. 2 is a cross-sectional view illustrating an example of a channel structure included in the semiconductor device shown in FIG. 1.

FIG. 3 is an enlarged plan view illustrating a part of the semiconductor device shown in FIG. 1.

FIG. 4 is a cross-sectional view illustrating a part of a circuit region included in the semiconductor device shown in FIG. 1.

FIG. 5A to FIG. 5J are cross-sectional views illustrating a manufacturing method of a semiconductor device according to an embodiment.

FIG. 6 is a cross-sectional view schematically illustrating a semiconductor device according to an embodiment.

FIG. 7 is a view schematically illustrating an electronic system including a semiconductor device according to an embodiment.

FIG. 8 is a perspective view schematically illustrating an electronic system including a semiconductor device according to an embodiment.

FIG. 9 is a cross-sectional view schematically illustrating a semiconductor package according to an embodiment.

FIG. 10 is a cross-sectional view schematically illustrating a semiconductor package according to an embodiment.

### DETAILED DESCRIPTION

The present disclosure will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

Descriptions of the embodiments may omit descriptions of features unrelated to the present disclosure in order to clearly describe the present disclosure. The same or similar components may be denoted using the same reference numeral throughout the present specification.

Further, since the sizes and thicknesses of portions, regions, members, units, layers, films, etc. shown in the accompanying drawings may be arbitrarily shown for better understanding and convenience of explanation, embodiments of the present disclosure are not limited to the illustrated sizes and thicknesses. In the drawings, thicknesses of portions, regions, members, units, layers, films, etc. may be enlarged or exaggerated for convenience of explanation.

It will be understood that when a component such as a layer, film, region, or substrate is referred to as being “on” or “connected” or “coupled” to another component, it may be directly on, connected, or coupled to the other component or an intervening component may also be present. In contrast, when a component is referred to as being “directly on”, “directly connected to”, or “directly coupled to” another component, or as “contacting” or “in contact with” another element (or using any form of the word “contact”), there is no intervening component present at the point of contact. Further, when a component is referred to as being “on” or “above” a reference component the reference is in reference to the orientation of the figure and does not necessarily refer to “on” or “above” the reference component in an opposite direction of gravity.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

In addition, unless explicitly described to the contrary, the word “comprise”, and variations such as “comprises” or “comprising”, will be understood to imply the inclusion of stated elements but not the exclusion of any other elements.

Further, throughout the specification, the phrases “on a plan view” and “in a plan view” may indicate a view where a portion is viewed from above or a top portion, and the phrases phrase “on a cross-section” and “in a cross-section” may indicate a side view of a cross-section taken along a vertical direction.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

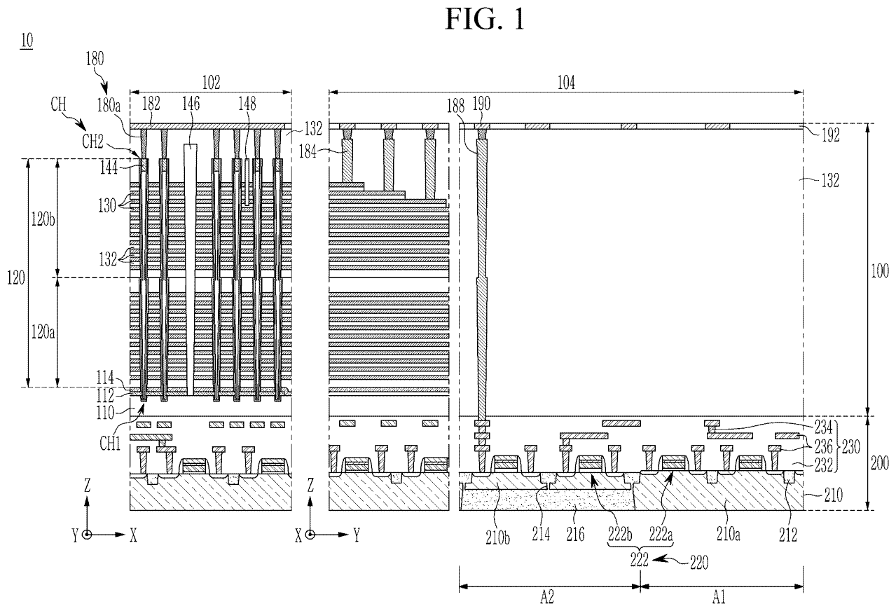

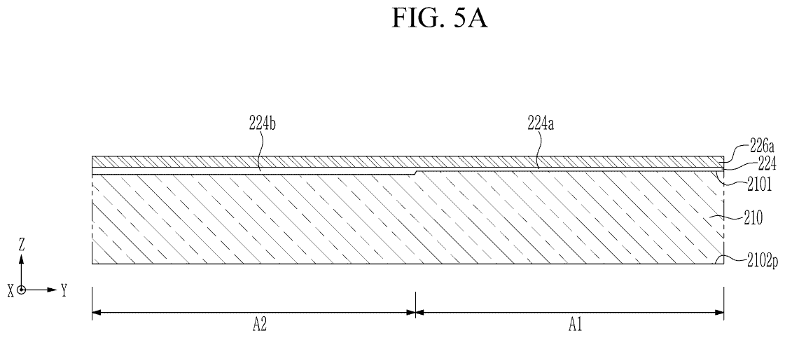

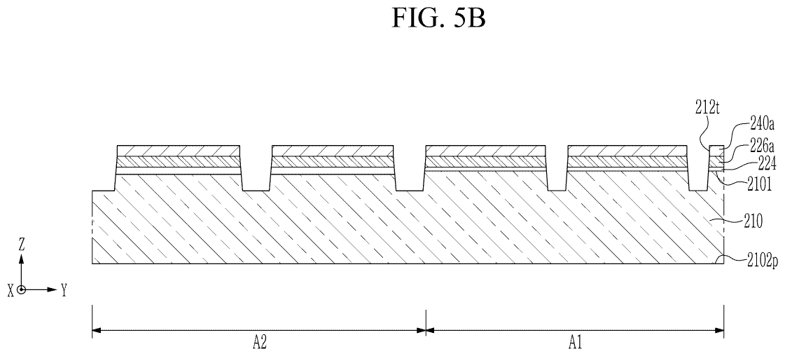

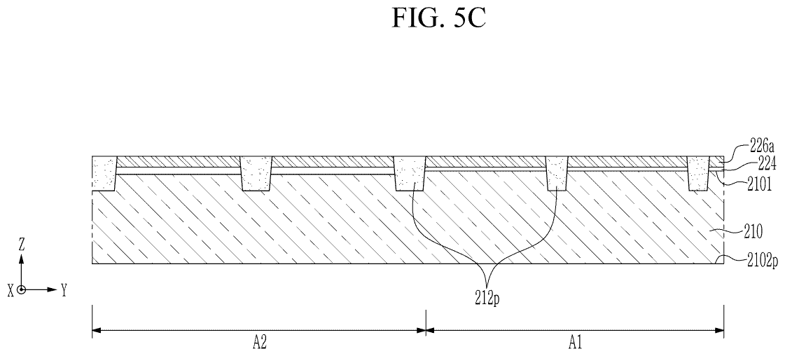

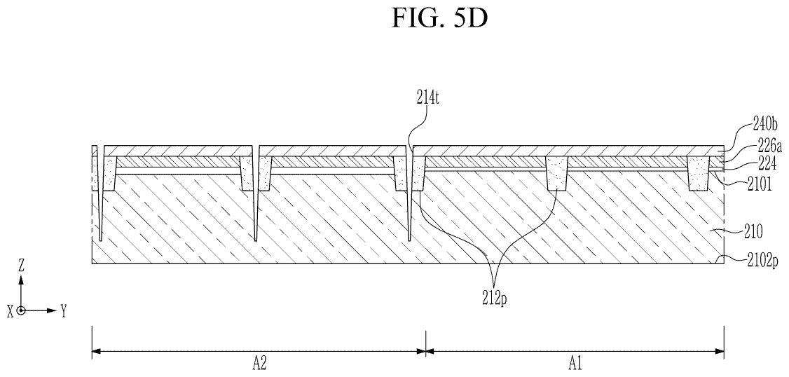

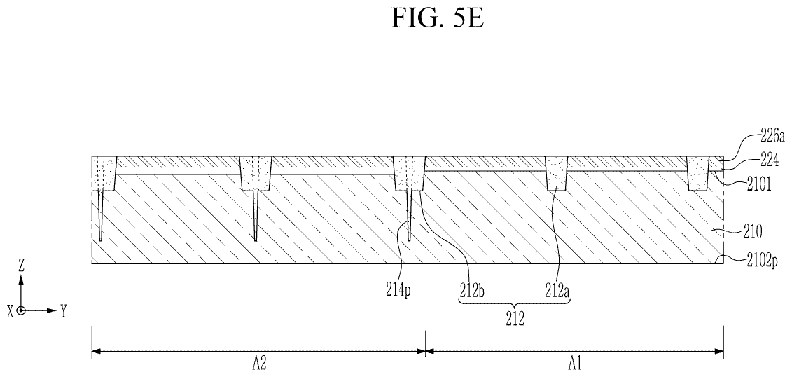

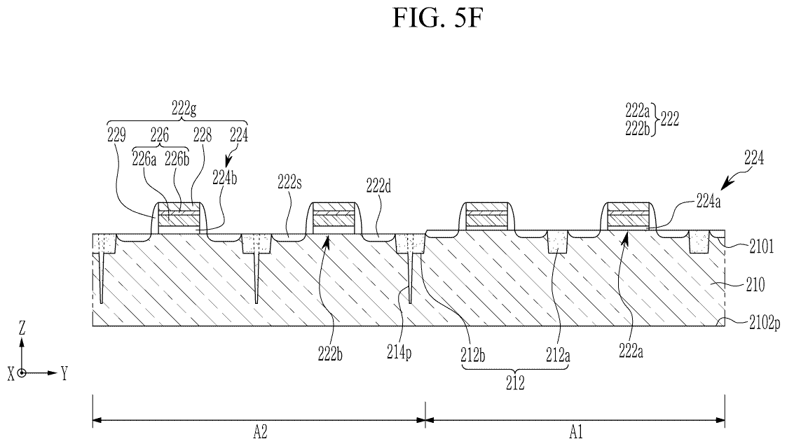

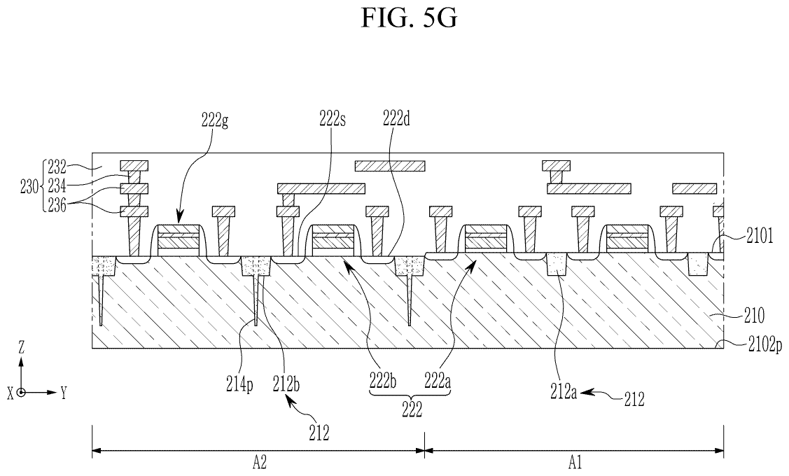

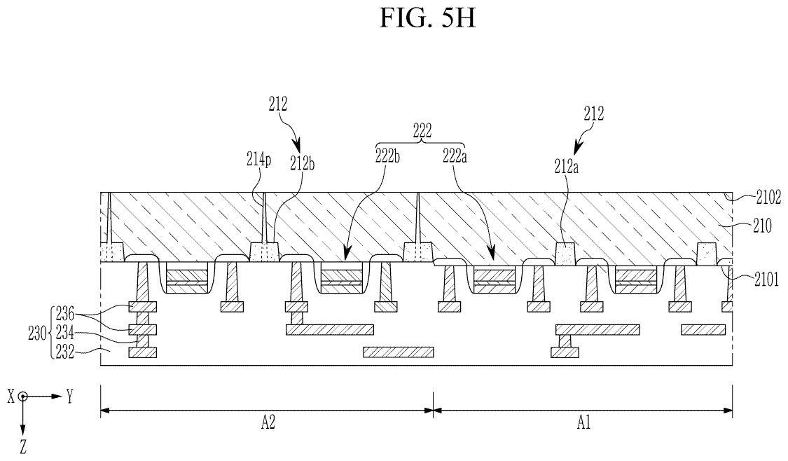

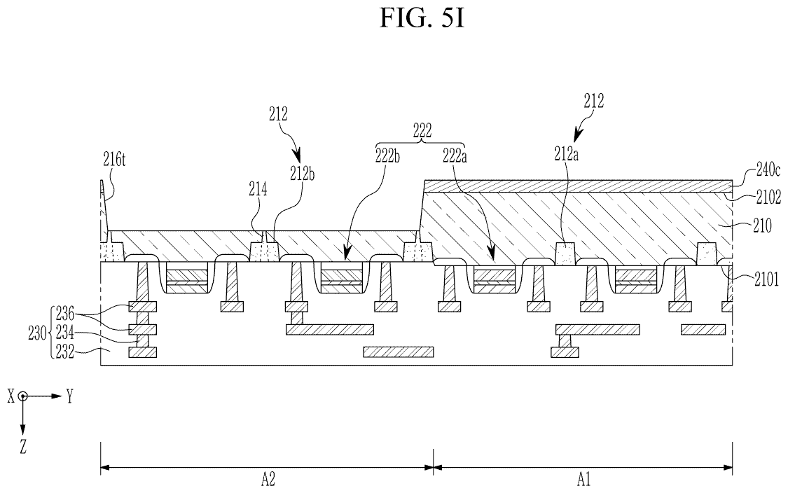

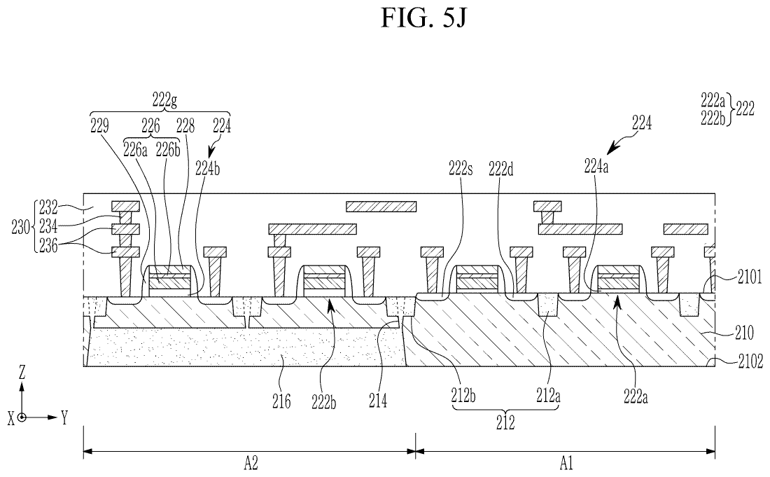

Hereinafter, with reference to FIG. 1 to FIG. 4, FIG. 5A to FIG. 5J, a semiconductor device and a manufacturing method for manufacturing the same according to an embodiment will be described in detail.

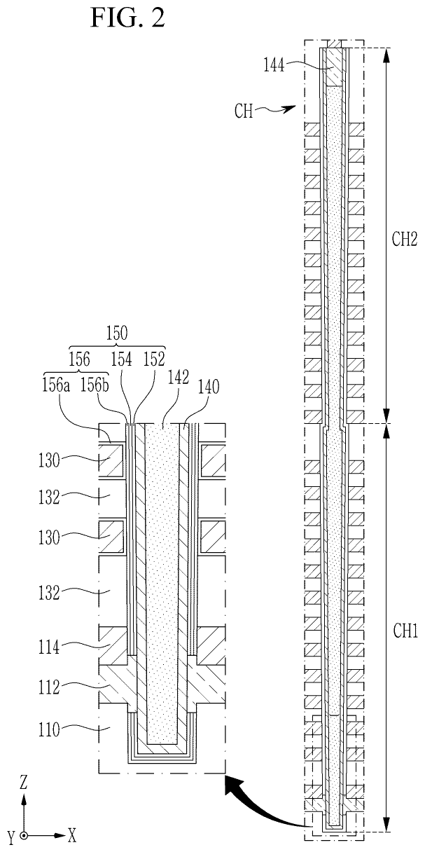

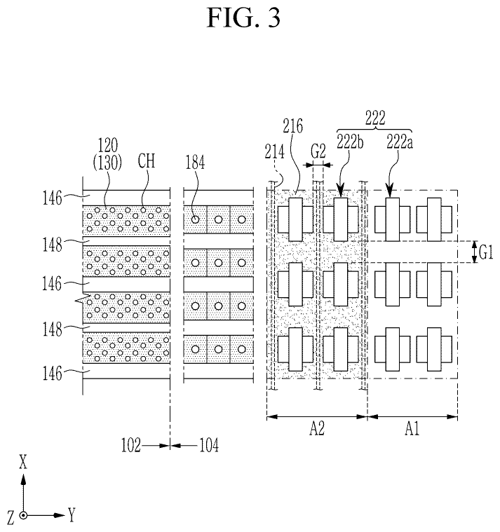

FIG. 1 is a cross-sectional view schematically illustrating a semiconductor device 10 according to an embodiment, and FIG. 2 is a cross-sectional view illustrating an example of a channel structure CH included in the semiconductor device 10 shown in FIG. 1. FIG. 3 is an enlarged plan view illustrating a part of the semiconductor device 10 shown in FIG. 1. For simple illustration and clear understanding, a portion of a cell region 100 where the channel structure CH is positioned, a portion of the cell region 100 where a gate contact portion 184 is positioned, and a portion of a circuit region 200 where a plurality of transistors 222 are positioned are mainly illustrated in FIG. 3.

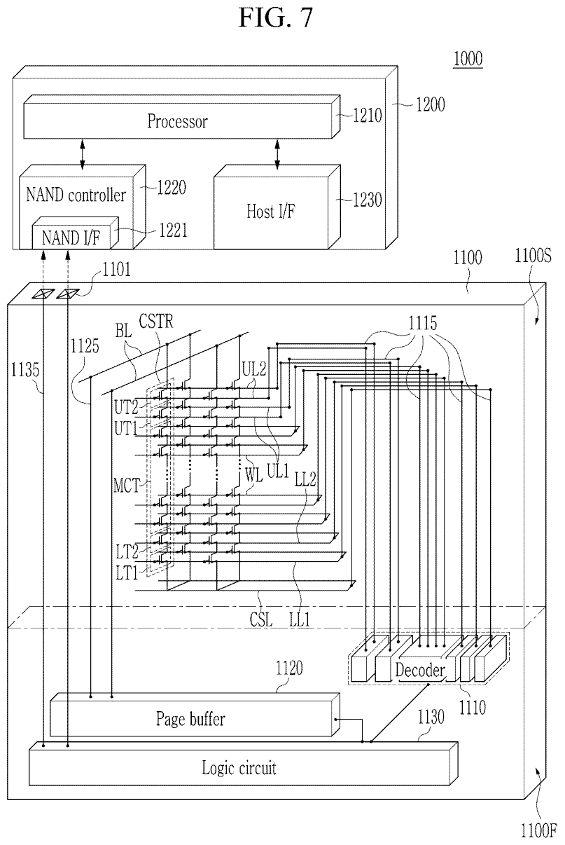

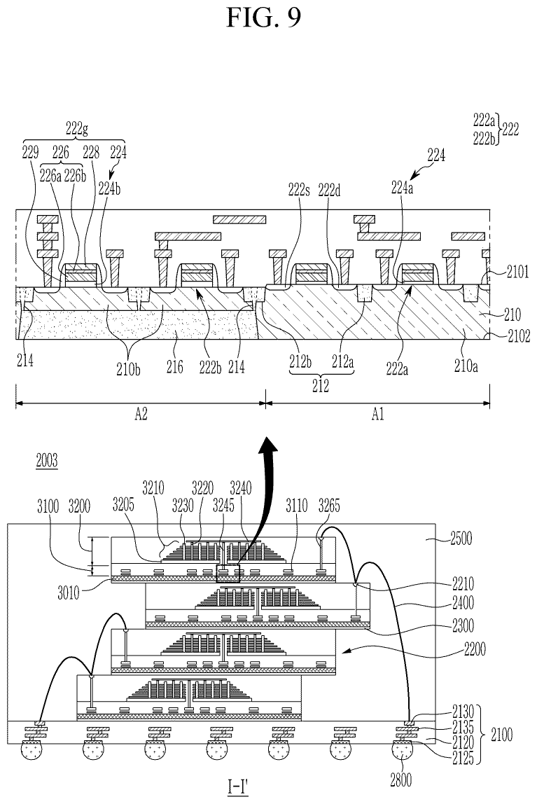

Referring to FIG. 1 to FIG. 3, a semiconductor device 10 according to an embodiment may include a cell region 100 including a memory cell structure and a circuit region 200 including a peripheral circuit structure controlling an operation of the memory cell structure. For example, the circuit region 200 and the cell region 100 may correspond to a first structure 1100F and a second structure 1100S of a semiconductor device 1100 included in an electronic system 1000 shown in FIG. 7, respectively. In some embodiments, the circuit region 200 and the cell region 100 may be portions of a semiconductor chip 2200 shown in FIG. 9 including a first structure 3100 and a second structure 3200, respectively.

Here, the circuit region 200 may include the peripheral circuit structure on a first substrate 210, and the cell region 100 may include a gate stacking structure 120 and the channel structure CH on a second substrate 110 as the memory cell structure. The circuit region 200 may include a first wiring portion 230, and the cell region 100 may include a second wiring portion 180 electrically connected to the memory cell structure.

In an embodiment, the cell region 100 may be on the circuit region 200. Accordingly, an area corresponding to the circuit region 200 does not need to be secured separately from the cell region 100. Therefore, an area of the semiconductor device 10 may be reduced. However, the embodiments are not limited thereto, and the circuit region 200 may be disposed next to the cell region 100. Various other modifications are possible.

The cell region 100 may include a cell array region 102 and a connection region 104. The gate stacking structure 120 and the channel structure CH may be on the second substrate 110 in the cell array region 102. A structure that connects the gate stacking structure 120 and/or the channel structure CH in the cell array region 102 to the circuit region 200 or an external circuit may be in the cell array region 102 and/or the connection region 104.

In an embodiment, the second substrate 110 may include a semiconductor layer formed of and/or including a semiconductor material. For example, the second substrate 110 may be a semiconductor substrate including and/or formed of a semiconductor material or may be a semiconductor substrate in which a semiconductor layer is on a base substrate. For example, the second substrate 110 may include and/or be formed of silicon, germanium, silicon-germanium, silicon on insulator, germanium on insulator, or the like. Here, the semiconductor layer included in the second substrate 110 may be doped with a p-type dopant or an n-type dopant. For example, the p-type dopant may include boron, gallium, or the like, and the n-type dopant may include phosphorus (P), arsenic (As), or the like. However, the embodiments are not limited to a material of the second substrate 110, a conductive type of the dopant doped to the semiconductor layer, or the like.

The gate stacking structure 120 and the channel structure CH may be positioned in the cell array region 102. The gate stacking structure 120 may include cell insulation layers 132 and gate lines 130 alternately stacked on a first surface (e.g., a front surface or an upper surface) of the second substrate 110. The cell insulation layers 132 may extend vertically above the uppermost gate line 130 and horizontally to the connection region. The channel structure CH may extend in a direction that is transverse to the second substrate 110 (a Z-axis direction in the drawings) while penetrating the gate stacking structure 120.

In an embodiment, horizontal conductive layers 112 and 114 may be provided between the second substrate 110 and the gate stacking structure 120 in the cell array region 102. The horizontal conductive layers 112 and 114 may electrically connect (e.g., directly connect) the channel structure CH and the second substrate 110. The horizontal conductive layers 112 and 114 may include a first horizontal conductive layer 112 and/or a second horizontal conductive layer 114 sequentially disposed on the second substrate 110. The first horizontal conductive layer 112 may act as a part of a common source line of the semiconductor device 10. For example, the first horizontal conductive layer 112 may act as the common source line together with the second substrate 110.

The first and the second horizontal conductive layers 112 and 114 may be formed of and/or include a semiconductor material (e.g., polycrystalline silicon). For example, the first horizontal conductive layer 112 may include a polycrystalline silicon layer formed of and/or including a dopant. The embodiments are not limited thereto. The second horizontal conductive layer 114 may include a material (e.g., an insulating material) that is different from a material of the first horizontal conductive layer 112, or in some embodiments the second horizontal conductive layer 114 might not be provided.

The gate stacking structure 120 in which the cell insulation layers 132 and the gate lines 130 are alternately stacked may be disposed on the second substrate 110 (e.g., on the first and second horizontal conductive layers 112 and 114 on the second substrate 110).

The gate line 130 may be formed of and/or include any of various conductive materials. For example, the gate line 130 may be formed of and/or include a metal material such as tungsten (W), copper (Cu), aluminum (Al), or the like, polycrystalline silicon, metal nitride (e.g., titanium nitride (TiN), tantalum nitride (TaN), or the like), or a combination thereof. As shown in an enlarged view of FIG. 2, a part of a blocking layer 156 (e.g., a first blocking layer 156a) including an insulating material may be outside of the gate line 130 (e.g., may be disposed on an external surface of the gate line 130). The cell insulation layer 132 may be formed of and/or include any of various insulating materials. For example, the cell insulation layer 132 may be formed of and/or include silicon oxide, silicon nitride, silicon oxynitride, a low dielectric constant material having a lower dielectric constant than silicon oxide, or a combination thereof.

In an embodiment, the channel structure CH may be formed to penetrate the gate stacking structure 120 and extend in a direction that is transverse to the second substrate 110 (e.g., a direction perpendicular to the second substrate 110 or a Z-axis direction in the drawings).

The channel structure CH may include a channel layer 140 and a gate dielectric layer 150 on the channel layer 140 between the gate line 130 and the channel layer 140. The channel structure CH may further include a core insulation layer 142 at an inside of the channel layer 140. In some embodiments, the core insulation layer 142 might not be provided. The channel structure CH may further include a channel pad 144 on the channel layer 140 and/or the gate dielectric layer 150. The gate dielectric layer 150 between the gate line 130 and the channel layer 140 may include a tunneling layer 152, a charge storage layer 154, and a blocking layer 156 sequentially on the channel layer 140.

Each channel structure CH may form one memory cell string, and a plurality of channel structures CH may be spaced apart from each other while forming rows and columns in a plan view. For example, a plurality of channel structures CH may be disposed to form any of various shapes such as a lattice shape, a zigzag shape, or the like in a plan view. The channel structure CH may have a pillar shape. For example, in a cross-sectional view, the channel structure CH may have an inclined side surface so that a width of the channel structure CH decreases as the channel structure CH goes to the second substrate 110 according to an aspect ratio. However, the embodiments are not limited thereto, and an arrangement, a structure, a shape, or the like of the channel structure CH may be variously modified.

The channel layer 140 may be formed of and/or include a semiconductor material (e.g., polycrystalline silicon). The core insulation layer 142 may include any of various insulating materials. For example, the core insulation layer 142 may be formed of and/or include silicon oxide, silicon nitride, silicon oxynitride, or a combination thereof.

The tunneling layer 152 may be formed of and/or include an insulating material that is capable of tunneling a charge (e.g., silicon oxide, silicon oxynitride, or the like). The charge storage layer 154 may be used as a data storage region, and the charge storage layer 154 may be formed of and/or include a polycrystalline silicon, a silicon nitride, or the like. The blocking layer 156 may be formed of and/or include an insulating material that is capable of preventing an undesirable flow of charge into the gate line 130. The blocking layer 156 may be formed of and/or include, for example, silicon oxide, silicon nitride, silicon oxynitride, a high dielectric constant material having a higher dielectric constant than silicon oxide, or a combination thereof. In an embodiment, the blocking layer 156 may include a first blocking layer 156a including a portion that extends horizontally along the gate line 130 and a second blocking layer 156b that extends vertically between the first blocking layer 156a and the charge storage layer 154.

However, materials, stacking structures, or the like of the channel layer 140, the core insulation layer 142, and the gate dielectric layer 150 may be variously modified and the embodiments are not limited thereto.

The channel pad 144 may cover an upper surface of the core insulation layer 142 and be disposed to be electrically connected to the channel layer 140. The channel pad 144 may be formed of and/or include a conductive material (e.g., polycrystalline silicon doped with a dopant), but the embodiments are not limited thereto.

In an embodiment, the gate stacking structure 120 may include a plurality of gate stacking structures 120a and 120b sequentially stacked. By sequentially stacking the gate stacking structures 120a and 120b, a number of stacked gate lines 130 may be increased and thus a number of memory cells may be increased with a stable structure. In FIG. 1, it is illustrated as an example that the gate stacking structure 120 includes two gate stacking structures 120a and 120b. In some embodiments, the gate stacking structure 120 may include one gate stacking structure or three or more gate stacking structures.

When the plurality of gate stacking structures 120a and 120b are provided as in the above, the channel structure CH may include a plurality of channel structures CH1 and CH2 that respectively penetrate the plurality of gate stacking structures 120a and 120b and are electrically connected to each other. In a cross-sectional view, each of the plurality of channel structures CH may have an inclined side surface such that a width of the channel structure CH decreases as the channel structure CH goes to the second substrate 110 according to an aspect ratio. A bent portion due to a difference in widths of the plurality of channel structures CH may be provided at a connection portion of the plurality of channel structures CH. In some embodiments, the plurality of channel structures CH1 and CH2 may have an inclined side surface that is continuously extended without the bent portion. In FIG. 2, it is illustrated as an example that the gate dielectric layer 150, the channel layer 140, and the core insulation layer 142 of the plurality of channel structures CH1 and CH2 may have an integral structure in which they continuously extend. In some embodiments, the gate dielectric layer 150, the channel layer 140, and the core insulation layer 142 of the plurality of channel structures CH1 and CH2 may be separately formed and be electrically connected to each other. In some embodiments, a separate channel pad may be additionally disposed at a connection portion of the plurality of channel structures CH1 and CH2. As such, the embodiments are not limited to a shape of a plurality of channel structures CH1 and CH2 shown in the figures.

In an embodiment, the gate stacking structure 120 may be divided into a plurality of portions in a plan view by a separation structure 146 extending in a direction that is transverse to the second substrate 110 (e.g., in a direction perpendicular to the second substrate 110 or a Z-axis direction in the drawings) to penetrate the gate stacking structure 120. An upper separation region 148 may be at an upper portion of the gate stacking structure 120. In a plan view, the separation structure 146 and/or the upper separation region 148 may extend in a first direction (a Y-axis direction in the drawings) and be spaced apart from each other at predetermined intervals in a second direction (an X-axis direction in the drawings) that is transverse to the first direction.

The separation structure 146 and/or the upper separation region 148 may be filled with any of various insulating materials (e.g., may be formed of and/or include any of the various insulating materials). For example, the separation structure 146 or the upper separation region 148 may be formed of and/or include an insulating material such as silicon oxide, silicon nitride, or silicon oxynitride. However, the embodiments are not limited thereto, and a structure, a shape, a material, or the like of the separation structure 146 or the upper separation region 148 may be variously modified.

The connection region 104 and the second wiring portion 180 may be provided to connect the gate stacking structure 120 and the channel structure CH in the cell array region 102 to the circuit region 200 or an external circuit. The connection region 104 may be at a periphery of the cell array region 102 and a part of the second wiring portion 180 may be in the connection region 104 (e.g., the second wiring portion 180 may extend from the cell array region 102 to the connection region 104).

The second wiring portion 180 may include a member electrically connecting the gate line 130, the channel structure CH, the horizontal conductive layers 112 and 114, and/or the second substrate 110 to the circuit region 200 or the external circuit. For example, the second wiring portion 180 may include a bit line 182, a gate contact portion 184, a source contact portion, a through plug 188, a contact via 180a connected to each of a respective bit line 182, a respective gate contact portion 184, a respective source contact portion, and/or a respective through plug 188, and a connection wiring 190 connecting the bit line 182, the gate contact portion 184, the source contact portion, the through plug 188, and the contact via 180a.

The bit line 182 may extend in the second direction (an X-axis direction in the drawings) that is transverse to the first direction in which the gate line 130 extends. The bit line 182 may be electrically connected to the channel structure CH (e.g., the channel pad 144) through the contact via 180a (e.g., a bit line contact via) that penetrates the cell insulation layer 132.

In the connection region 104, a plurality of gate contact portions 184 may penetrate the cell gate insulation layer 132 to be electrically connected to a plurality of gate lines 130, respectively, extended to the connection region 104. In the drawings, it is illustrated as an example that the plurality of gate lines 130 have a stair shape in one direction or a plurality of directions in the connection region 104, but the embodiments are not limited thereto. In the connection region 104, the source contact portion may penetrate the cell insulation layer 132 to be electrically connected to the horizontal conductive layers 112 and 114 and/or to the second substrate 110. The through plug 188 may penetrate through the gate stacking structure 120 or may be at an outside of the gate stacking structure 120 (e.g., external to such that it does not pass through the gate stacking structure 120) to be electrically connected to the first wiring portion 230 of the circuit region 200.

In FIG. 1, it is illustrated as an example that each of the gate contact portions 184, the source contact portion, and/or the through plug 188 has an inclined side surface such that a width of each of the gate contact portion 184, the source contact portion, and/or the through plug 188 decreases as each of the gate contact portion 184, the source contact portion, and/or the through plug 188 approaches the second substrate 110. A bent portion (e.g., the inclined side surface may extend laterally to increase the width of the respective component) may be provided at a boundary portion of the plurality of gate stacking structures 120a and 120b. However, the embodiments are not limited thereto. In some embodiments, the source contact portion and/or the through plug 188 might not include the bent portion at the boundary portion of the plurality of gate stacking structures 120a and 120b. Other modifications are possible.

In FIG. 1, it is illustrated as an example that the connection wiring 190 is a single layer disposed on the same plane as the bit line 182 and a second insulation layer 192 fills a portion in the second wiring portion 180 surrounding the connection wiring 190 in the same plane as the bit line 182. However, this is a brief illustration for convenience. For an electrical connection with the bit line 182, the gate contact portion 184, the source contact portion, and/or the through plug 188, the connection wiring 190 may include a plurality of wiring layers and may further include a contact via electrically connecting at least a portion of two adjacent wiring layers.

The bit line 182 connected to the channel structure CH, the gate line 130, the horizontal conductive layers 112 and 114, and/or the second substrate 110 may be electrically connected to a circuit element 220 of the circuit region 200 by an electrical connection between the second wiring portion 180 and the first wiring portion 230.

The circuit region 200 may include the first substrate 210, the circuit element 220, and the first wiring portion 230 which may be disposed on the first substrate 210.

The first substrate 210 may be a semiconductor substrate formed of and/or including a semiconductor material. For example, the first substrate 210 may be a semiconductor substrate including and/or formed of a semiconductor material or may be a semiconductor substrate in which a semiconductor layer is disposed on a base substrate. For example, the first substrate 210 may include single-crystalline or polycrystalline silicon, epitaxial silicon, germanium, silicon-germanium, silicon on insulator (SOI), germanium on insulator (GOI), or the like.

The circuit element 220 on the first substrate 210 may include any of various circuit elements that control an operation of the memory cell structure in the cell region 100. For example, the circuit element 220 may constitute a peripheral circuit structure such as a decoder circuit 1110 (refer to FIG. 7), a page buffer 1120 (refer to FIG. 7), a logic circuit 1130 (refer to FIG. 7), or the like.

For example, the circuit element 220 may include a transistor 222. In an embodiment, the circuit element 220 may include a plurality of transistors 222 including a first transistor 222a and a second transistor 222b, which will be described later in more detail. The circuit element 220 may include active elements such as the transistor or the like, or may also include a passive element such as a capacitor, a resistor, an inductor, or the like.

The first wiring portion 230 on the first substrate 210 may be electrically connected to the circuit element 220. In an embodiment, the first wiring portion 230 may include a plurality of wiring layers 236 that are spaced apart from each other while interposing a first insulation layer 232 therebetween (e.g., the plurality of wiring layers 236 may be electrically insulated from one another by the first insulation layer) and portions of wiring layers 236 may be electrically connected by a contact via 234 to form an electrical path between portions of adjacent wiring layers 236. The wiring layers 236 or the contact via 234 may be formed of and/or include any of various conductive materials, and the first insulation layer 232 may be formed of and/or include any of various insulating materials. For example, a wiring layer 236, among the plurality of wiring layers 236, disposed at an uppermost level adjacent to the cell region 100 may include or constitute a pad portion to which the gate contact portion 184, a through plug 188, or the like may be connected.

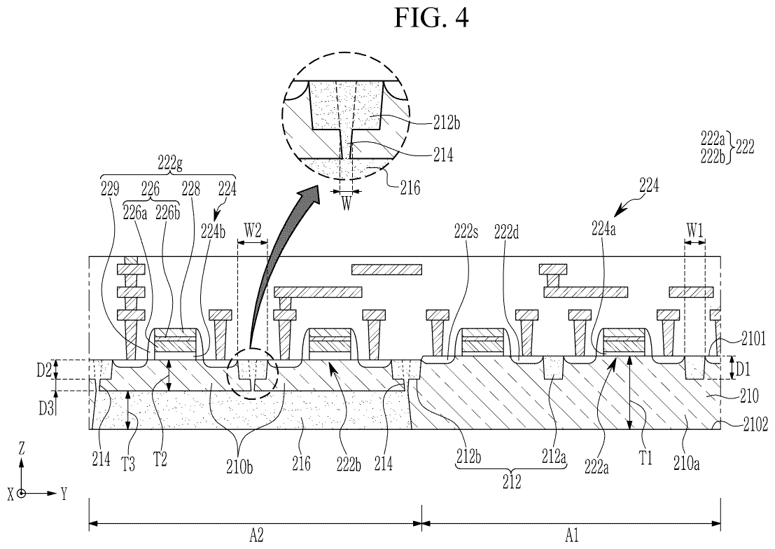

Referring to FIG. 4 together with FIG. 1 to FIG. 3, the plurality of transistors 222 including the first transistor 222a and the second transistor 222b will be described in more detail. FIG. 4 is a cross-sectional view illustrating a part of the circuit region 200 included in the semiconductor device 10 shown in FIG. 1.

Referring to FIG. 4, in an embodiment, the first substrate 210 may be a semiconductor substrate including a first transistor region A1 and a second transistor region A2. The first substrate 210 may be provided with the plurality of transistors 222. The plurality of transistors 222 may include the first transistor 222a and the second transistor 222b. The first transistor 222a may be disposed in the first transistor region A1. The second transistor 222b may have higher operating voltage than the first transistor 222a and may be disposed in the second transistor region A2.

The first transistor 222a may be a low-voltage (LV) transistor having relatively low operating voltage, and the second transistor 222b may be a high-voltage (HV) transistor having relatively high operating voltage. For example, the first transistor 222a may have operating voltage of 0.1 V to 10 V, and the second transistor 222b may have operating voltage larger than the operating voltage of the first transistor 222a, for example, 10 V to 100 V. However, the embodiments are not limited to values of the operating voltages of the first and second transistors 222a and 222b.

The first transistor 222a, which is the low-voltage transistor, may have a high-speed operation property and excellent reliability, and thus, may be a transistor that requires high-speed operation. The second transistor 222b, which is the high-voltage transistor, may be a transistor that generates or transmits high voltage. For example, at least some of the transistors included in the decoder circuit 1110 (refer to FIG. 7), the page buffer 1120 (refer to FIG. 7), or the like may be configured as the second transistor 222b.

For simple illustration and clear understanding, it is illustrated as an example that the first transistor region A1 where the first transistor 222a is positioned and the second transistor region A2 where the second transistor 222b is positioned are adjacent at a lower portion of the connection region 104 in the drawings. For example, it is illustrated as an example that the second transistor 222b or the second transistor region A2 may be adjacent to, or below, the through plug 188, and the first transistor 222a or the first transistor region A1 may be laterally adjacent to the above second transistor 222b or second transistor region A2. In some embodiments, the first transistor region A1 where the first transistor 222a is positioned and the second transistor region A2 where the second transistor 222b is positioned may be together at a lower portion of the cell array region 102. In some embodiments, one of the first transistor region A1 where the first transistor 222a is positioned and the second transistor region A2 where the second transistor 222b is positioned may be at a lower portion of the cell array region 102, and the other of the first transistor region A1 where the first transistor 222a is positioned and the second transistor region A2 where the second transistor 222b is positioned may be at a lower portion of the connection region 104. Further, positions of the first transistor region A1 and the second transistor region A2 may be variously modified.

In an embodiment, the plurality of transistors 222, that is, the first transistor 222a and the second transistor 222b, have a planar structure. For example, each of the plurality of transistors 222 includes a gate structure 222g on the first substrate 210, and source and drain regions 222s and 222d formed by doping a dopant to portions of the first substrate 210. The gate structure 222g may include a gate insulation layer 224, a gate electrode 226, a gate capping layer 228, and a gate spacer 229.

The gate insulation layer 224 may be formed of and/or include at least one of oxide, nitride, oxynitride, a high dielectric constant material having a dielectric constant higher than a dielectric constant of silicon oxide, and a low dielectric constant material having a dielectric constant lower than a dielectric constant of silicon oxide. For example, the gate insulation layer 224 may be formed of and/or include at least one of silicon oxide, silicon nitride, silicon oxynitride, hafnium oxide, aluminum oxide, and tantalum oxide. The gate insulation layer 224 may include one insulation layer or may include a plurality of insulation layers.

The first gate insulation layer 224a included in the first transistor 222a and the second gate insulation layer 224b included in the second transistor 222b may be formed of and/or include the same material. However, the embodiments are not limited thereto, and the first gate insulation layer 224a included in the first transistor 222a and the second gate insulation layer 224b included in the second transistor 222b may be formed of and/or include different materials.

In an embodiment, a thickness of the second gate insulation layer 224b included in the second transistor 222b may be larger than a thickness of the first gate insulation layer 224a included in the first transistor 222a. According to this, the second transistor 222b, which is a high-voltage transistor, may stably withstand a high potential difference between the gate electrode 226 and the source and drain regions 222s and 222d.

The gate electrode 226 on the gate insulation layer 224 may be formed of and/or include a conductive material. For example, the gate electrode 226 may be formed of and/or include at least one of a metal, a metal alloy, metal nitride, metal silicide, and a doped semiconductor material. Here, the metal or the metal alloy forming and/or included in the gate electrode 226 may include at least one of titanium, tungsten, molybdenum, aluminum, copper, cobalt, tantalum, and ruthenium. The metal nitride included in the gate electrode 226 may include at least one of titanium nitride, tungsten nitride, molybdenum nitride, and tantalum nitride. The gate electrode 226 may further include metal oxide or metal oxynitride in which the above material is oxidized. The doped semiconductor material may include a semiconductor material (e.g., a polycrystalline semiconductor material) doped with an n-type or p-type dopant.

In the drawings, it is illustrated as an example that the gate electrode 226 may include a first electrode layer 226a including a semiconductor layer, and a second electrode layer 226b including a metal-including layer having metal. However, the embodiments are not limited thereto, and a material, a stacking structure, or the like of the gate electrode 226 may be variously modified.

The gate capping layer 228 may be on the gate electrode 226. The gate capping layer 228 may be formed of and/or include any of various materials such as oxide, nitride, oxynitride, or the like. For example, the gate capping layer 228 may be formed of and/or include at least one of silicon oxide, silicon nitride, and silicon oxynitride. The gate capping layer 228 may act as a mask layer when the gate insulation layer 224 and the gate electrode 226 are formed. In the drawings, it is illustrated as an example that the gate spacer 229 is on a side surface of the gate capping layer 228. In some embodiments, the capping layer 228 may be on the gate spacer 229.

The gate spacer 229 may be formed of and/or include any of various insulating materials such as oxide, nitride, oxynitride, a low dielectric constant material, or the like. For example, the gate spacer 229 may be formed of and/or include at least one of silicon oxide, silicon nitride, and silicon oxynitride or may be formed of and/or include a material including the above material and carbon. The gate spacer 229 may include one insulation layer or may include a plurality of insulation layers.

The gate spacer 229 may be at a side surface of the gate structure 222g to insulate the gate structure 222g, the source region 222s, and/or the drain regions 222d. For example, the gate spacers 229 may be located at least at both sides of the gate electrode 226 in a transverse direction (a Y-axis direction in the drawings) transverse to the gate electrode 226, and the gate spacers 229 may extend in an extension direction of the gate electrode 226 (an X-axis direction in the drawings).

However, the embodiments are not limited thereto. The gate insulation layer 224, the gate electrode 226, the gate capping layer 228, the gate spacer 229 and/or the source and drain regions 222s and 222d may have various materials, structures, or the like.

In FIG. 4, it is illustrated as an example that a lower surface of the first gate insulation layer 224a included in the first transistor 222a is higher than a lower surface of the second gate insulation layer 224b included in the second transistor 222b, and an upper surface of the first gate insulation layer 224a included in the first transistor 222a and an upper surface of the second gate insulation layer 224b included in the second transistor 222b are on the same plane. In some embodiments, the lower surface of the first gate insulation layer 224a included in the first transistor 222a and the lower surface of the second gate insulation layer 224b included in the second transistor 222b may be on the same plane, and the upper surface of the first gate insulation layer 224a included in the first transistor 222a may be higher than the upper surface of the second gate insulation layer 224b included in the second transistor 222b. Various other modifications are possible.

In a plan view, the source and drain regions 222s and 222d may be at portions of the first substrate 210 at opposing sides of the gate structure 222g. For example, the source and drain regions 222s and 222d may be portions of the first substrate 210 doped with an n-type dopant or a p-type dopant. In this instance, a conductive type of the dopant in the source and drain regions 222s and 222d may be opposite to a conductive type of the dopant in the first substrate 210.

In an embodiment, an isolation portion 212 may be at a first surface (e.g., a front surface or an upper surface) of the first substrate 210. In this instance, the isolation portion 212 may be at a boundary of the plurality of transistors 222 in the first transistor region A1 and the second transistor region A2 (e.g., the isolation portion 212 may be between two adjacent transistors). In the first transistor region A1 and the second transistor region A2, the isolation portion 212 may separate active regions of adjacent transistors corresponding to the first and/or the second transistors 222a and 222b at the front surface of the first substrate 210. For example, the isolation portion 212 may separate the source and drain regions 222s and 222d of adjacent transistors of the plurality of transistors 222a and 222b at the front surface of the first substrate 210.

For example, the isolation portion 212 may have a shallow trench isolation (STI) structure separating the active regions of adjacent transistors of the first and second transistors 222a and 222b. In a cross-section view perpendicular to the extension direction of the gate structure 222g (an X-axis in the drawings), the isolation portion 212 may have an inclined side surface such that a width of the isolation portion 212 gradually decreases from the first surface 2101 of the first substrate 210 to a second surface (e.g., a lower surface) 2102 of the first substrate 210. This may be because a first trench 212t (refer to FIG. 5B) for forming the isolation portion 212 is formed by an etching process performed at the first surface 2101 of the first substrate 210.

In an embodiment, a second width W2 of a second isolation portion 212b in the second transistor region A2 may be larger than a first width W1 of a first isolation portion 212a in the first transistor region A1. In this instance, the first width W1 may be the maximum width of the first isolation portion 212a, and the second width W2 may be the maximum width of the second isolation portion 212b. The wider width of the second isolation portion 212b in the second transistor region A2 where the second transistor 222b, which is a high-voltage transistor, is positioned, may stably separate the active region of the second transistor 222b. In some embodiments, the second width W2 of the second isolation portion 212b in the second transistor region A2 may be the same as or smaller than the first width W1 of the first isolation portion 212a in the first transistor region A1.

In FIG. 4, it is illustrated as an example that the lower surface of the first gate insulation layer 224a is higher than the lower surface of the second gate insulation layer 224b, and a lower surface of the first isolation portion 212a and a lower surface of the second isolation portion 212b are on the same plane, and thus, a first thickness D1 of the first isolation portion 212a (e.g., the depth of the first isolation portion) is larger than a second thickness D2 of the second isolation portion 212b (e.g., the depth of the second isolation portion). However, in some embodiments, the lower surface of the first isolation portion 212a and the lower surface of the second isolation portion 212b may not be on the same plane, or the first thickness D1 may be the same or smaller than the second thickness D2. Various other modifications are possible.

In an embodiment, a recess insulator 216 may be at the second surface 2102 (e.g., the lower surface) of the first substrate 210 in the second transistor region A2. A separation insulator 214 may be included that may be connected to the recess insulator 216 at a lateral boundary of the second transistor 222b in the second transistor region A2. For example, the separation insulator 214 may connect the isolation portion 212 and the recess insulator 216 in the second transistor region A2.

The separation insulator 214 may have a deep trench isolation (DTI) structure separating the active regions of adjacent pairs of the second transistor 222b. In a cross-section view perpendicular to the extension direction of the gate structure 222g (an X-axis in the drawings), the separation insulator 214 may have an inclined side surface such that a width of the separation insulator 214 gradually decreases from the first surface 2101 of the first substrate 210 to the second surface 2102 of the first substrate 210. This may be because a second trench 214t (refer to FIG. 5d) for forming the separation insulator 214 may be formed by an etching process performed at the first surface 2101 of the first substrate 210.

The separation insulator 214 may be disposed at a portion of the second transistor region A2 where the isolation portion 212 is positioned. Because the separation insulator 214 may be disposed where the isolation portion 212 is positioned a separate space to form the separation insulator 214 might not be needed, which is advantageous in terms of space. Here, an insulation portion between a lower surface of the second isolation portion 212b adjacent to the second surface 2102 of the first substrate 210 and an upper surface of the recess insulator 216 adjacent to the first surface 2101 of the first substrate 210 may be the separation insulator 214.

In this instance, a width W of the separation insulator 214 may be smaller than a width of the isolation portion 212 (e.g., the first width W1 of the first isolation portion 212a or the second width W2 of the second isolation portion 212b). The width of the separation insulator 214 may be a width in the transverse direction (a Y-axis in the drawings) that is transverse to the gate structure 222g and may be the maximum width of the separation insulator 214 or a width of the separation insulator 214 at a portion adjacent to the lower surface of the second isolation portion 212b.

For example, a ratio of the width of the separation insulator 214 to the first width W1 or the second width W2 of the isolation portion 212 may be in the range of 1% to 10%. More particularly, a ratio (W/W2) of the width of the separation insulator 214 to the second width W2 of the second isolation portion 212b in the second transistor region A2 may be in the range of 1% to 10%. If the ratio (W/W2) is less than 1%, the width of the separation insulator 214 might not be sufficient to effectively separate the active regions of adjacent pairs of the second transistor 222b. If the ratio (W/W2) is greater than 10%, an area of the separation insulator 214 may exceed a predetermined value and may waste space. However, the embodiments are not limited thereto. Therefore, in some embodiments, the ratio of the width of the separation insulator 214 to the width W1 or W2 of the isolation portion 212 may be less than 1% or larger than 10%.

The separation insulator 214 may protrude from the lower surface of the second isolation portion 212b toward the second surface 2102 of the first substrate 210 by a third thickness D3 (e.g., the distance between the lower surface of the second isolation portion 212b and the upper surface of the recess insulator 216). This may be because the second trench 214t may be formed to be deeper than the first trench 212t in a manufacturing process such that the separation insulator 214 protrudes from the lower surface of the second isolation portion 212b.

As in the above, the isolation portion 212 in the first transistor region A1 and the second transistor region A2 has the first width W1 or the second width W2, which is relatively large, to stably separate the active region of adjacent transistors. In the second transistor region A2, the separation insulator 214 has a relatively small with W and protrudes from the lower surface of the second isolation portion 212b. Therefore, a second portion 210b of the first substrate 210 may divided into smaller portions that may each be stably separated to correspond to the second transistors 222b in the second transistor region A2 in at least in one direction without using additional space.

The recess insulator 216 may span an entire region of the second transistor region A2 in a plan view. In this instance, the recess insulator 216 is not provided in the first transistor region A1 and is provided in the second transistor region A2 at least partially or locally. The recess insulator 216 may be a bulk insulator replacing a part of the first substrate 210 in the second transistor region A2.

In the second transistor region A2, the second portion 210b of the first substrate 210 are on the recess insulator 216 in a thickness direction to form a semiconductor-on-insulator structure, for example, a silicon-on-insulator (SOI) structure in the second transistor region A2. The recess insulator 216 may correspond locally or at least partially to the second transistor region A2, and the circuit region 200 may have a kind of a partial semiconductor-on-insulator structure, for example, a partial silicon-on-insulator (SOI) structure by the recess insulator 216. In the first transistor region A1, an insulator, an insulation portion, or an insulation layer might not be provided between the first surface 2101 of the first substrate 210 and the second surface 2102 of the first substrate 210, and a first portion 210a of the first substrate may span an entire portion between the first surface 2101 of the first substrate 210 and the second surface 2102 of the first substrate 210.

The recess insulator 216 may be formed by filling an insulating material to a recess 216t (refer to FIG. 5I) where a part of the first substrate 210 is removed in a thickness direction (a Z-axis in the drawings).

Due to the recess insulator 216, the second surface 2102 of the first substrate 210 in the first transistor region A1 may be positioned higher than the second surface 2102 at the second portion 210b of the first substrate 210 in the second transistor region A2. Due to the recess insulator 216, the second surface 2102 at the second portion 210b of the first substrate 210 in the second transistor region A2 may be at a recess of the first substrate 210 or may be closer to the first surface 2101 of the first substrate 210 than the second surface 2102 at the first portion 210a of the first substrate 210 in the first transistor region A1.

Due to the recess insulator 216, a thickness T2 of the second portion 210b of the first substrate 210 in the second transistor region A2 may be smaller than a thickness T1 of the first portion 210a of the first substrate 210 in the first transistor region A1. For example, the thickness T1 of the first portion 210a may be substantially the same as a sum of the thickness T2 of the second portion 210b and a thickness T3 of the recess insulator 216. However, the embodiments are not limited thereto, and the thickness T1 of the first portion 210a may be smaller or larger than the sum of the thickness T2 of the second portion 210b and the thickness T3 of the recess insulator 216.

In a cross-section view perpendicular to the extension direction of the gate structure 222g (an X-axis in the drawings), the recess insulator 216 may have an inclined side surface such that a width of the recess insulator 216 gradually decreases from the second surface 2102 of the first substrate 210 to the first surface 2101 of the first substrate 210. This may be because the recess 216t for forming the recess insulator 216 may be formed by an etching process performed at the second surface 2102 of the first substrate 210. As such, an inclined direction of a side surface of the recess insulator 216 may be opposite to an inclined direction of a side surface of the isolation portion 212 or the separation insulator 214.

The isolation portion 212, the separation insulator 214, or the recess insulator 216 may be formed of and/or include any of various insulating materials which may fill a trench in the first substrate 210. For example, the isolation portion 212, the separation insulator 214, or the recess insulator 216 may be formed of and/or include an insulating material such as oxide, nitride, or oxynitride. As an example, the isolation portion 212, the separation insulator 214, or the recess insulator 216 may be formed of and/or include an insulating material such as silicon oxide, silicon nitride, or silicon oxynitride. However, the embodiments are not limited thereto. A material of the isolation portion 212, the separation insulator 214, or the recess insulator 216 may be variously modified.

In an embodiment, the separation insulator 214 and the recess insulator 216 may constitute a partition insulator entirely separating the active regions of adjacent transistors of the second transistor 222b in at least one direction. Each second transistor 222b is structurally separated from another transistor 222 (e.g., the first transistor 222a and/or another second transistor 222b) by the partition insulator, and thus, an additional doping region for separating the second transistors 222b may not be needed. The separation insulator 214 and/or the recess insulator 216, or the partition insulator may be provided in the second transistor region A2 and may not be provided in the first transistor region A1. That is, the first transistor region A1 where the first transistor 222a is positioned and the second transistor region A2 where the second transistor 222b is positioned may have different structures. Thereby, the second transistors 222b may be stably separated in the second transistor region A2 where the second transistor 222b is positioned.

In this instance, the recess insulator 216 which may span an entire region of the second transistor region A2 in a plan view may have an area larger than an area of the separation insulator 214 at the boundary of a transistor of the second transistors 222b in the second transistor region A2. In a cross-sectional view, in the second transistor region A2, the plurality of separation insulators 214 may be connected (e.g., directly connected) to the plurality of second isolation portions 212b, respectively, and the plurality of the separation insulator 214 may be connected (e.g., directly connected) to a single recess insulator 216.

The plurality of first transistors 222a and the plurality of second transistors 222b may be arranged in the one direction (e.g., the transverse direction that is transverse to the gate structure 222g or a Y-axis direction in the drawings). In the one direction, the first substrate 210 in the first transistor region A1 may include a single portion (i.e., a single first portion 210a) corresponding to the plurality of first transistors 222a, and the first substrate 210 in the second transistor region A2 may include a plurality of portions (i.e., the plurality of second portions 210b) corresponding to the plurality of second transistors 222b, respectively.

In this instance, in the one direction (e.g., the transverse direction that is transverse to the gate structure 222g or the Y-axis direction in the drawings), a pair of the separation insulators 214 may be at both sides of one second transistor 222b. The pair of the separation insulators 214 may be connected together to the recess insulator 216. Then, in the one direction or in a cross-section (e.g., a YZ plane in the drawings) perpendicular to the separation insulator 214, the second portion 210b of the first substrate 210 where the second transistor 222b is positioned may be entirely separated from another portion of the first substrate 210 (i.e., the first portion 210a of the first substrate 210 or another second portion 210b of the first substrate 210) by the pair of separation insulators 214 and the recess insulator 216.

In an embodiment, the separation insulator 214 may include a portion extending in the extension direction of the gate structure 222g (an X-axis direction in the drawings) at the boundary of second transistors 222b adjacent to each other in the transverse direction (a Y-axis direction in the drawings) that is transverse to the gate structure 222g. For example, a plurality of separation insulators 214 extending in the extension direction (an X-axis direction in the drawings) may be spaced apart from each other at a regular interval in the transverse direction (a Y-axis direction in the drawings).

A gap between the plurality of second transistor 222b in the extension direction of the gate structure 222g (an X-axis direction in the drawings) may be relatively large for an insulation property. For example, a first gap G1 between the plurality of second transistors 222b (i.e., the distance between adjacent second transistors 222b) in the extension direction of the gate structure 222g (an X-axis direction in the drawings) may be larger than a second gap G2 between the plurality of second transistors 222b in the transverse direction that is transverse to the gate structure 222g (a Y-axis direction in the drawings). Considering the above, a separation insulator 214 at the boundary between adjacent transistors of the plurality of second transistors 222b may have a relatively small second gap G2. Then, in the extension direction of the gate structure 222g, the second portion 210b of the first substrate 210 corresponding to the plurality of second transistors 222b may be connected to another portion of the first substrate 210. Accordingly, an electrical connection structure of the second transistor 222b may be maintained.

However, the embodiments are not limited thereto, and a structure of the separation insulator 214 may be variously modified.

In an embodiment, the width W of the separation insulator 214 may be smaller than the thickness T2 of the second portion 210b of the first substrate 210 in the second transistor region A2. It is sufficient that the separation insulator 214 has a width to be connected to the recess insulator 216. In some embodiments, the width W of the separation insulator 214 may be the same as or larger than the thickness T2 of the second portion 210b of the first substrate 210 in the second transistor region A2.

In an embodiment, the thickness T3 of the recess insulator 216 may be larger than the thickness T2 of the second portion 210b of the first substrate 210 in the second transistor region A2. It is sufficient that the thickness T2 of the second portion 210b of the first substrate 210 has a thickness to have a depletion region during operation of the second transistor 222b. When the thickness T2 of the second portion 210b of the first substrate 210 is small, the operation of the second transistor 222b may be easily controlled. In some embodiments, the thickness T3 of the recess insulator 216 may be the same as or smaller than the thickness T2 of the second portion 210b of the first substrate 210.

In an embodiment, a third thickness D3 of the separation insulator 214 may be smaller than the first thickness D1 of the first isolation portion 212a or the second thickness D2 of the second isolation portion 212b. The third thickness D3 of the separation insulator 214 may be smaller than the thickness T3 of the recess insulator 216. It is sufficient that the separation insulator 214 has the depth to be connected to the recess insulator 216. However, the embodiments are not limited thereto. In some embodiments, the third thickness D3 of the separation insulator 214 may be the same as or larger than the first thickness D1 of the first isolation portion 212a or the second thickness D2 of the second isolation portion 212b. The third thickness D3 of the separation insulator 214 may be the same as or larger than the thickness T3 of the recess insulator 216.

In the drawings, it is illustrated as an example that the extension direction of the gate structure 222g (an X-axis direction in the drawings) crosses an extension direction of the gate line 130, and the transverse direction that is transverse to the gate structure 222g (a Y-axis direction in the drawings) is parallel to the extension direction of the gate line 130, but the embodiments are not limited thereto. The extension direction of the gate structure 222g (an X-axis direction in the drawings) may be parallel to the extension direction of the gate line 130, and the transverse direction that is transverse to the gate structure 222g (a Y-axis direction in the drawings) may cross the extension direction of the gate line 130. Other various modifications are possible.

According to the embodiment, the thickness T2 of the second portion 210b of the first substrate 210 in the second transistor region A2 may be reduced by the recess insulator 216 in the second transistor region A2. Thereby, the depletion capacitance (cdm) of the second transistor 222b in the second transistor region A2 may be reduced. Accordingly, drain induced barrier lowering (DIBL) may be improved and leakage current of the second transistor 222b may be reduced. Due to the separation insulator 214 and the recess insulator 216, the second portion 210b of the first substrate 210 where the second transistor 222b is positioned is entirely separated or insulated from another portion of the first substrate 210 at least in one direction. In this instance, there is no doping region for electrically separating or insulating the active region of the second transistor 222b, and thus, performance degradation of the second transistor 222b by the doping region may be prevented or suppressed. Accordingly, a gap between the second transistors 222b may be reduced, thereby reducing the area of the circuit region 200 or the semiconductor device 10. That is, performance and integration of the circuit region 200 or the semiconductor device 10 including the second transistor 222b may be improved.

The circuit region 200 including the first substrate 210, the first transistor 222a, and the second transistor 222b may be included in the semiconductor device 10 including the cell region 100 having the memory cell structure. For example, the semiconductor device 10 including the circuit region 200 according to the embodiment may be a flash memory device. This is because the high-voltage transistor or the second transistor 222b of the flash memory device is operated by a higher voltage than a transistor of another memory device or another semiconductor device. Accordingly, performance and integration may be effectively improved in the flash memory device including the high-voltage transistor or the second transistor 222b operated by large operating voltage.

Conventionally, for separation or isolation of the active region of the high-voltage transistor, a size of a separation portion was increased or a doping region having dopants was formed at a boundary of the active region in the semiconductor substrate. Due to the doping region, the separation or insulation of the active region of the high-voltage transistor might not be stable, and properties of the high-voltage transistor may be deteriorated. As a result, performance of the circuit region or the semiconductor device may be degraded, and there is a limit to reducing an area of the circuit region or the semiconductor device.

An example of a manufacturing method of a semiconductor device 10 having the above structure will be described in detail with reference to FIG. 5A to FIG. 5J together with FIG. 1 to FIG. 4. To the extent that an element is not described in detail below, it may be understood that the element is at least similar to a corresponding element that has been described elsewhere within the present disclosure. A portion which is not described in the above may be described in detail hereafter.

FIG. 5A to FIG. 5J are cross-sectional views illustrating a manufacturing method of a semiconductor device according to an embodiment. In FIG. 5A to FIG. 5J, a portion corresponding to the portion of FIG. 4 is mainly illustrated, and a manufacturing method of a circuit region 200 of a semiconductor device 10 will be mainly described below.

As shown in FIG. 5A, a gate insulation layer 224 and a first electrode layer 226a may be formed on a first surface 2101 of a first substrate 210. The gate insulation layer 224 and the first electrode layer 226a may be formed by any of various methods such as deposition.

In FIG. 5A, it is illustrated as an example that the first surface 2101 or an upper surface of the first substrate 210 in a first transistor region A1 is higher than the first surface 2101 or an upper surface of the first substrate 210 in the second transistor region A2, and a lower surface of a first gate insulation layer 224a in the first transistor region A1 is higher than a lower surface of the second gate insulation layer 224b in a second transistor region A2. It is illustrated as an example that an upper surface of the first gate insulation layer 224a in the first transistor region A1 is on the same plane as an upper surface of the second gate insulation layer 224b in the second transistor region A2. The first substrate 210 and the gate insulation layer 224 having the above structure may be formed by any of various processes.

However, the embodiments are not limited thereto. In some embodiments, the first surface 2101 or the upper surface of the first substrate 210 in the first transistor region A1 may be on the same plane as the first surface 2101 or the upper surface of the first substrate 210 in the second transistor region A2, and the lower surface of the first gate insulation layer 224a in the first transistor region A1 may be on the same plane as the lower surface of the second gate insulation layer 224b in the second transistor region A2. The upper surface of the second gate insulation layer 224b in the second transistor region A2 may be higher than the upper surface of the first gate insulation layer 224a in the first transistor region A1. Various other modifications are possible.

Subsequently, as shown in FIG. 5B and FIG. 5C, a first preliminary insulation layer 212p may be formed at the first surface 2101 of the first substrate 210. In this instance, the first preliminary insulation layer 212p may correspond to a boundary of a transistor of a plurality of transistors 222 (refer to FIG. 5F) that will be provided in the first and second transistor regions A1 and A2. More particularly, the first preliminary insulation layer 212p may correspond a boundary of a first transistor 222a (refer to FIG. 5F) that will be provided in the first transistor region A1 and a boundary of a second transistor 222b (refer to FIG. 5F) that will be provided in the second transistor region A2, respectively.

More particularly, as shown in FIG. 5B, a first mask layer 240a that exposes the boundary of the plurality of transistors 222 may be formed on the first surface 2101 of the first substrate 210 (e.g., on the gate insulation layer 224 and the first electrode layer 226a). A first trench 212t may be formed by etching a part of the first substrate 210, the gate insulation layer 224, and the first electrode layer 226a using the first mask layer 240a at the first surface 2101 of the first substrate 210. As an etching process, any of various processes such as dry etching may be applied.

Subsequently, as shown in FIG. 5C, the first preliminary insulation layer 212p that fills the first trench 212t (refer to FIG. 5B) may be formed. For example, the first preliminary insulation layer 212p may be formed by filling the first trench 212t with an insulating material and then performing a chemical-mechanical polishing process.

Any of various processes, for examples, a deposition processes (e.g., chemical vapor deposition or physical vapor deposition), or the like may be used as a process for forming the insulating material. The first mask layer 240a may be removed during the chemical-mechanical polishing process, but the embodiments are not limited thereto.

In the embodiment, it is illustrated as an example that the first trench 212t for forming an isolation portion 212 (refer to FIG. 5E) is formed after the gate insulation layer 224 and the first electrode layer 226a are formed. In this instance, an upper surface of the first preliminary insulation layer 212p may be polished by the chemical-mechanical polishing process so that the upper surface of the first preliminary insulation layer 212p is on the same plane as the upper surface of the first electrode layer 226a. In this instance, the first electrode layer 226a may act as an etching stop layer in the chemical-mechanical polishing process.

However, the embodiments are not limited thereto. In some embodiments, the first trench 212t and/or the first preliminary insulation layer 212p may be formed before the gate insulation layer 224 and/or the first electrode layer 226a is formed. In this instance, the upper surface of the first preliminary insulation layer 212p may be polished by the chemical-mechanical polishing process so that the upper surface of the first preliminary insulation layer 212p is on the same plane as the upper surface of the first substrate 210 or the upper surface of the gate insulation layer 224. In some embodiments, the first trench 212t and/or the first preliminary insulation layer 212p may be formed after the gate insulation layer 224 and a gate electrode 226 are formed on the first surface 2101 of the first substrate 210. In this instance, the upper surface of the first preliminary insulation layer 212p may be polished by the chemical-mechanical polishing process so that the upper surface of the first preliminary insulation layer 212p is on the same plane as the upper surface of the gate electrode 226. Various other modifications are possible.

Subsequently, as shown in FIG. 5D and FIG. 5E, a second preliminary insulation layer 214p may be formed at the first surface 2101 of the first substrate 210. In this instance, the second preliminary insulation layer 214p may correspond to the boundary of a transistor of the second transistor 222b in the second transistor region A2 but might not be formed in the first transistor region A1.

More particularly, as shown in FIG. 5D, a second mask layer 240b that exposes the boundary of the second transistor 222b may be formed on the first surface 2101 of the first substrate 210 (e.g., on the gate insulation layer 224 and the first electrode layer 226a). A second trench 214t may be formed by etching a part of the first substrate 210, the gate insulation layer 224, and the first electrode layer 226a using the second mask layer 240b at the first surface 2101 of the first substrate 210.

The second mask layer 240b may cover an entire portion of the first transistor region A1 and expose a region where the boundary of the second transistor 222 will be positioned in the second transistor region A2. Thus, the second trench 214t might not be in the first transistor region A1 and may be at the boundary of a transistor of the second transistor 222b in the second transistor region A2. As an etching process, any of various processes such as dry etching may be applied.

Subsequently, as shown in FIG. 5E, a second preliminary insulation layer 214p that fills the second trench 214t (refer to FIG. 5D) may be formed. For example, the second preliminary insulation layer 214p may be formed by filling the second trench 214t with an insulating material and then performing a chemical-mechanical polishing process. The first preliminary insulation layer 212p (refer to FIG. 5D) and the second preliminary insulation layer 214p may fill an entire portion of the first trench 212t (refer to FIG. 5B) to form an isolation portion 212.

Any of various processes, for examples, a deposition processes (e.g., chemical vapor deposition or physical vapor deposition), or the like may be used as a process for forming the insulating material. Since the second trench 214t has a relatively small width and a relatively large depth, the second preliminary insulation layer 214p may be formed by atomic layer deposition (ALD). For example, the process of forming the first preliminary insulation layer 212p May be different from the process of forming the second preliminary insulation layer 214p and/or a process of forming a recess insulator 216 (refer to FIG. 5J). However, the embodiments are not limited thereto, and the process of forming the second preliminary insulation layer 214p may be the same as the process of forming the first preliminary insulation layer 212p and/or the process of forming the recess insulator 216. The second mask layer 240b may be removed during the chemical-mechanical polishing process, but the embodiments are not limited thereto.

In the embodiment, it is illustrated as an example that the second trench 214t for forming a separation insulator 214 (refer to FIG. 5I) is formed after the gate insulation layer 224 and the first electrode layer 226a are formed. In this instance, an upper surface of the second preliminary insulation layer 214p may be polished by the chemical-mechanical polishing process so that the upper surface of the second preliminary insulation layer 214p is on the same plane as the upper surface of the first electrode layer 226a. In this instance, the first electrode layer 226a may act as an etching stop layer in the chemical-mechanical polishing process.

However, the embodiments are not limited thereto. In some embodiments, the second trench 214t and/or the second preliminary insulation layer 214p may be formed before the gate insulation layer 224 and/or the first electrode layer 226a is formed. In this instance, the upper surface of the second preliminary insulation layer 214p may be polished by the chemical-mechanical polishing process so that the upper surface of the second preliminary insulation layer 214p is on the same plane as the upper surface of the first substrate 210 or the upper surface of the gate insulation layer 224. In some embodiments, the second trench 214t and/or the second preliminary insulation layer 214p may be formed after the gate insulation layer 224 and the gate electrode 226 are formed on the first surface 2101 of the first substrate 210. In this instance, the upper surface of the second preliminary insulation layer 214p may be polished by the chemical-mechanical polishing process so that the upper surface of the second preliminary insulation layer 214p is on the same plane as the upper surface of the gate electrode 226. Various other modifications are possible.

Subsequently, as shown in FIG. 5F, a plurality of transistors 222 including a first transistor 222a and a second transistor 222b may be formed in the first transistor region A1 and the second transistor region A2. That is, the plurality of transistors 222 respectively including a gate structure 222g and source and drain regions 222s and 222d may be formed.

More particularly, a second electrode layer 226b and a gate capping layer 228 may be formed on the first electrode layer 226a, and the gate insulation layer 224, the first electrode layer 226a, and the second electrode layer 226b may be patterned using the gate capping layer 228 as a mask. The gate spacer 229 may be formed on a side surface of the gate electrode 226, and source and drain regions 222s and 222d may be formed by using the gate capping layer 228 and the gate spacer 229 as a mask. For example, the source and drain regions 222s and 222d may be formed by any of various methods such as ion implantation processes. Any of various processes may be applied to the process of forming the plurality of transistors 222.

Together with the plurality of transistors 222, various circuit elements 220 may be further formed before or after the process of forming the plurality of transistors 222. Any of various processes may be applied to the process of forming the circuit element 220.

Subsequently, as shown in FIG. 5G, a first wiring portion 230 including a plurality of wiring layer 236 interposing a first insulation layer 232 therebetween and connected by a contact via 234 for forming a desired path may be formed. Any of various processes may be applied to the process of forming the first wiring portion 230.

Subsequently, as shown in FIG. 5H, a thinning process may be performed to remove a part of the first substrate 210 in a thickness direction in a state that a preliminary surface 2102p (refer to FIG. 5G) of the first substrate 210 is at an upper portion (e.g., the first substrate 210 may be inverted).

In this instance, a lower surface (an upper surface in FIG. 5H) of the second preliminary insulation layer 214p may act as a kind of an etching stop surface. Accordingly, a part of the first substrate 210 may be removed to the lower surface (the upper surface in FIG. 5H) of the second preliminary insulation layer 214p, and thus, a second surface 2102 of the first substrate 210 may be on the same plane as the lower surface (the upper surface of FIG. 5H) of the second preliminary insulation layer 214p. According to this, a part of the first substrate 210 may be stably removed to the lower surface (the upper surface in FIG. 5H) of the second preliminary insulation layer 214p. However, the embodiments are not limited thereto. Therefore, the second surface 2102 of the first substrate 210 may be lower or higher than the lower surface (the upper surface in FIG. 5H) of the second preliminary insulation layer 214p.

For example, the thinning process may be performed by a grinding process. According to this, a process time may be reduced by a high speed of the grinding. However, the embodiments are not limited thereto, and other processes such as a chemical-mechanical polishing process or the like may be applied.

Subsequently, as shown in FIG. 5I and FIG. 5J, a recess insulator 216 connected to the separation insulator 214 may be formed in the second transistor region A2 at the second surface 2102 of the first substrate 210.

More particularly, as shown in FIG. 5I, a third mask layer 240c that covers the first transistor region A1 and exposes an entire portion of the second transistor region A2 may be formed on the second surface 2102 of the first substrate 210. For example, the third mask layer 240c may be formed by a photolithography process. A recess 216t may be formed by etching a part of the first substrate 210 using the third mask layer 240c at the second surface 2102 of the first substrate 210.

The third mask layer 240c may cover an entire portion of the first transistor region A1 and expose an entire portion of the second transistor region A2. Thus, the recess 216t might not be in the first transistor region A1 and may be at the entire portion of the second transistor region A2. As an etching process, any of various processes such as wet etching and dry etching may be applied.

In FIG. 5I, it is illustrated as an example that a part of the second preliminary insulation layer 214p (refer to FIG. 5H) exposed to the second surface 2102 of the first substrate 210 is etched and the second preliminary insulation layer 214p in the recess 216t may be removed during the etching process, thereby forming the separation insulator 214. However, the embodiments are not limited thereto. In some embodiment, the second preliminary insulation layer 214p in the recess 216t might not be removed and thus may remain.

Subsequently, as shown in FIG. 5J, the recess insulator 216 that fills the recess 216t may be formed. For example, the recess insulator 216 may be formed by filling the recess 216t with an insulating material and then performing a chemical-mechanical polishing process.

Any of various processes, for examples, a deposition processes (e.g., chemical vapor deposition or physical vapor deposition), or the like may be used as a process for forming the insulating material. The third mask layer 240c may be removed during the chemical-mechanical polishing process, but the embodiments are not limited thereto. The chemical-mechanical polishing process may be performed such that a lower surface of the recess insulator 216 is on the same plane as the second surface 2102 of the first substrate 210 in the first transistor region A1.

According to the embodiment, the circuit region 200 including the recess insulator 216 and/or the separation insulator 214 in the second transistor region A2 may be easily manufactured. Thereby, the circuit region 200 or the semiconductor device 10 having improved performance and integration may be easily manufactured.

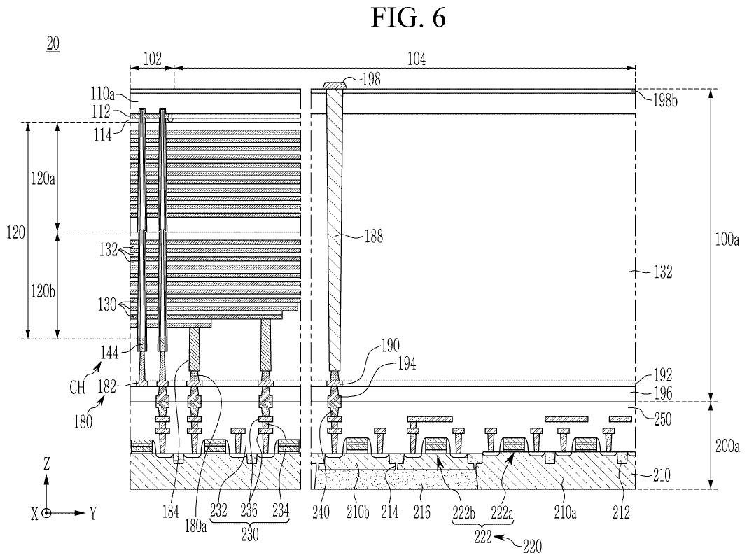

An embodiment and a modified embodiment thereof will be described in detail with reference to FIG. 6. To the extent that an element is not described in detail below, it may be understood that the element is at least similar to a corresponding element that has been described elsewhere within the present disclosure. Hereinafter, a portion which is not described in the above will be described in detail.

FIG. 6 is a cross-sectional view schematically illustrating a semiconductor device 20 according to an embodiment.

Referring to FIG. 6, a semiconductor device 20 according to an embodiment may have a chip-to-chip (C2C) structure bonded by a wafer bonding type. That is, a lower chip including a circuit region 200a having a first substrate 210 may be manufactured, an upper chip including a cell region 100a having a second substrate 110a may be manufactured, and then a semiconductor device 20 may be manufactured by bonding the lower chip and the upper chip.

The circuit region 200a may include a first substrate 210, a circuit element 220, a first wiring portion 230, and a first bonding structure 240 electrically connected to the first wiring portion 230 at a surface facing the cell region 100a. A region other than the first bonding structure 240 at the surface facing the cell region 100a may be covered by an insulation layer 250.

The cell region 100a may include a second substrate 110a, a gate stacking structure 120, a channel structure CH, a second wiring portion 180, and a second bonding structure 194 electrically connected the second wiring portion 180 at a surface facing the circuit region 200a. A region other than the second bonding structure 194 may be covered by an insulation layer 196.

In an embodiment, the second substrate 110a may be a semiconductor substrate formed of and/or including a semiconductor material. For example, the second substrate 110a may be a semiconductor substrate of a semiconductor material or may be a semiconductor substrate in which a semiconductor layer is on a base substrate. For example, the second substrate 110a may be formed of and/or include single-crystalline or polycrystalline silicon, germanium, silicon-germanium, silicon-on-insulator, germanium-on-insulator, or the like. In some embodiments, the second substrate 110a may be a supporting member including an insulation layer or an insulating material. This is because a semiconductor substrate provided in the cell region 100a may be removed after the cell region 100a is bonded to the circuit region 200a and the supporting member including the insulation layer or insulating material may be formed.

In an embodiment, the gate stacking structure 120 may be sequentially stacked on a lower portion of the second substrate 110a as shown in the drawing and may have a structure in which the gate stacking structure 120 shown in FIG. 1 is disposed in a vertically inverted manner. The channel structure CH penetrating the gate stacking structure 120 may have a structure in which the channel structure CH shown in FIG. 2 is disposed in a vertically inverted manner. Accordingly, in a cross-sectional view, the channel structure CH may have an inclined side surface such that a width of the channel structure CH decreases as the channel structure CH goes from the circuit region 200a to the second substrate 110a. The channel pad 144 and the second wiring portion 180 at the gate stacking structure 120 may be adjacent to the circuit region 200a.

For example, the first bonding structure 240 and/or the second bonding structure 194 may include aluminum, copper, tungsten, or an alloy including the same. For example, the first and second bonding structures 240 and 194 may include copper so that the cell region 100a and the circuit region 200a may be bonded (e.g., directly bonded) to each other by copper-to-copper bonding.

In FIG. 6, it is illustrated as an example that the gate stacking structure 120 includes a plurality of gate stacking structures. In some embodiment, the gate stacking structure may include one gate stacking structure or three or more gate stacking structures. Unless otherwise described, the description of the gate stacking structure 120 and the channel structure CH described with reference to FIG. 1 to FIG. 4 may be applied as it is. In FIG. 6, it is illustrated as an example that an electrical connection structure between the channel structure CH and the horizontal conductive layers 112 and 114 and/or the second substrate 110 is the same as that of FIG. 2. The embodiments are not limited thereto, and the electrical connection structure between the channel structure CH and the horizontal conductive layers 112 and 114 and/or the second substrate 110 may be variously modified.

The semiconductor device 20 according to an embodiment may include an input/output pad 198, and a through plug 188 or an input/output connection wiring electrically connected to the input/output pad 198. The through plug 188 or the input/output connection wiring may be electrically connected to a part of the second bonding structure 194. For example, the input/output pad 198 may be on an insulation layer 198b covering an outer surface of the second substrate 110a. According to an embodiment, an additional input/output pad electrically connected to the circuit region 200a may be provided.

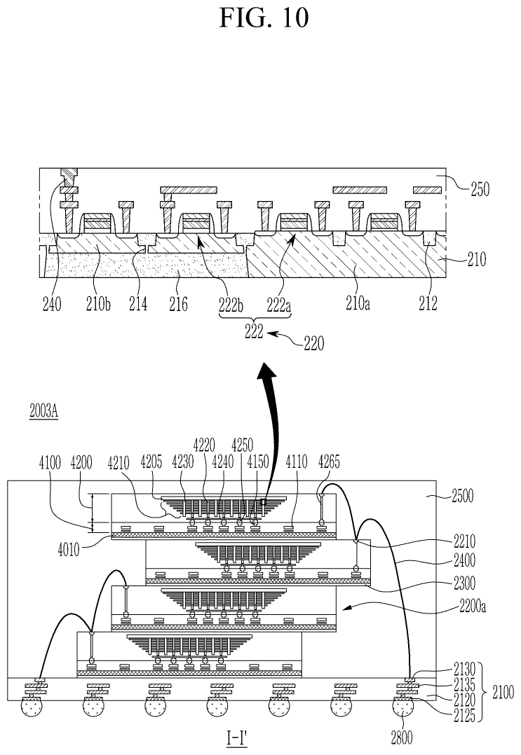

For example, the circuit region 200a and the cell region 100a may be portions corresponding to a first structure 1100F and a second structure 1100S of a semiconductor device 1100 included in an electronic system 1000 shown in FIG. 7, respectively. In some embodiments, the circuit region 200a and the cell region 100a may be regions including a first structure 4100 and a second structure 4200 of a semiconductor chip 2200 shown in FIG. 10, respectively.

An example of an electronic system including the semiconductor device will be described in detail below.

FIG. 7 is a view schematically illustrating an electronic system including a semiconductor device according to an embodiment.

Referring to FIG. 7, an electronic system 1000 according to an embodiment may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid-state drive (SSD) device, a universal serial bus (USB), a computing system, a medical device, or a communication device including one or a plurality of semiconductor devices 1100.

The semiconductor device 1100 may be a non-volatile memory device, and for example, may be a NAND flash memory device described with reference to FIG. 1 to FIG. 4, FIG. 5A to FIG. 5J, and FIG. 6. The semiconductor device 1100 may include a first structure 1100F and a second structure 1100S on the first structure 1100F. In some embodiments, the first structure 1100F may be next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. A number of lower transistors LT1 and LT2 and a number of upper transistors UT1 and UT2 may be variously modified according to an embodiment.

In an embodiment, the lower transistors LT1 and LT2 may include a ground selection transistor, and the upper transistors UT1 and UT2 may include a string selection transistor. The first and second gate lower lines LL1 and LL2 may be gate lines of the lower transistors LT1 and LT2, respectively. The word line WL may be a gate line of the memory cell transistor MCT, and the gate upper lines UL1 and UL2 may be gate lines of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 extending to the second structure 1100S within the first structure 1100F. The bit line BL may be electrically connected to the page buffer 1120 through a second connection wiring 1125 extending to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending to the second structure 1100S within the first structure 1100F.

The controller 1200 may include a processor 1210, a NAND controller 1220, and a host interface 1230. According to an embodiment, the electronic system 1000 may include the plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

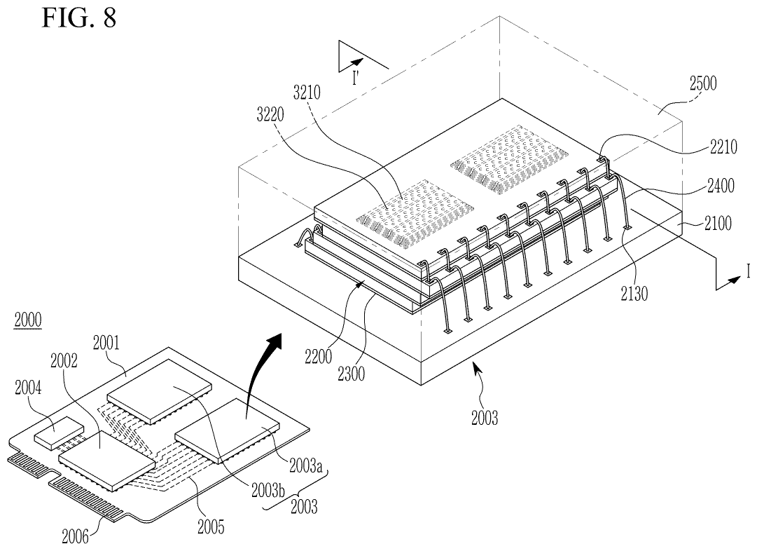

FIG. 8 is a perspective view schematically illustrating an electronic system including a semiconductor device according to an embodiment.

Referring to FIG. 8, an electronic system 2000 according to an embodiment may include a main substrate 2001, a controller 2002 on the main substrate 2001, one or more semiconductor packages 2003, and a DRAM 2004. The semiconductor package 2003 and the DRAM 2004 may be connected to the controller 2002 through a wiring pattern 2005 at the main substrate 2001.

The main substrate 2001 may include a connector 2006 including a plurality of pins coupled to an external host. A number and an arrangement of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), and an M-Phy for a universal flash storage (UFS). In an embodiment, the electronic system 2000 may operate by power supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003 and may improve an operating speed of the electronic system 2000.

The DRAM 2004 may be a buffer memory for mitigating or buffering a speed difference between the semiconductor package 2003, which is a data storage space, and the external host. The DRAM 2004 included in the electronic system 2000 may also be a kind of cache memory and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chip 2200 on the package substrate 2100, an adhesive layer 2300 at a lower surface of each semiconductor chip 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 7. Each semiconductor chip 2200 may include a gate stacking structure 3210 and a channel structure 3220. The semiconductor chip 2200 may include the semiconductor device described with reference to FIG. 1 to FIG. 4, FIG. 5A to FIG. 5J, and FIG. 6.

In an embodiment, the connection structure 2400 may be a bonding wire electrically connecting the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to the package upper pad 2130 of the package substrate 2100. According to an embodiment, in each of the first and second semiconductor packages 2003a and 2003b, the semiconductor chips 2200 may be electrically connected to each other by a connection structure including a through silicon via (TSV) instead of the connection structure 2400 using the bonding wire type.

In an embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring at the interposer substrate.

FIG. 9 and FIG. 10 are cross-sectional views schematically illustrating semiconductor packages according to embodiments, respectively. FIG. 9 and FIG. 10 respectively describe embodiments of the semiconductor package 2003 of FIG. 8, and conceptually illustrate a region obtained by cutting the semiconductor package 2003 of FIG. 8 along a line I-I′.

Referring to FIG. 9, in the semiconductor package 2003, the package substrate 2100 may be a printed circuit board. The package substrate 2100 may include a package substrate body portion 2120, a package upper pad 2130 at an upper surface of the package substrate body portion 2120, a lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the connection structure 2400. The package lower pad 2125 may be connected to a wiring pattern 2005 of the main substrate 2001 of the electronic system 2000, as shown in FIG. 8, through a conductive connection portion 2800.

The semiconductor chip 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacking structure 3210 on the common source line 3205, a channel structure 3220 and a separation structure 3230 penetrating the gate stacking structure 3210, a bit line 3240 electrically connected to the channel structure 3220, and a gate connection wiring electrically connected to a word line WL (refer to FIG. 7) of the gate stacking structure 3210.

In a semiconductor chip 2200 or a semiconductor device according to an embodiment, performance and integration of the semiconductor chip 2200a or the semiconductor device may be improved by a recess insulator 216 and/or a separation insulator 214 in a second transistor region A2.

Each of the semiconductor chips 2200 may include a through wiring 3245 that is electrically connected to a peripheral wiring 3110 of the first structure 3100 and extends into the second structure 3200. The through wiring 3245 may penetrate the gate stacking structure 3210 and may be further provided at an outside of the gate stacking structure 3210. Each semiconductor chip 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In an embodiment, in the semiconductor package 2003, a plurality of semiconductor chips 2200 may be electrically connected to each other by a connection structure 2400 having a bonding wire type. In some embodiments, the plurality of semiconductor chips 2200 or a plurality of portions constituting the plurality of semiconductor chips 2200 may be electrically connected by a connection structure including a through silicon via (TSV).

Referring to FIG. 10, in a semiconductor package 2003A, each semiconductor chip 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second bonding structure 4250 electrically connected to the channel structure 4220 and a word line WL (refer to FIG. 7) of the gate stacking structure 4210. For example, the second bonding structure 4250 may be electrically connected to the channel structure 4220 and the word line WL through a bit line 4240 electrically connected to the channel structure 4220 and a gate connection wiring electrically connected to the word line WL. The first bonding structure 4150 of the first structure 4100 and the second bonding structure 4250 of the second structure 4200 may be contact and bonded to each other. For example, a portion where the first bonding structure 4150 and the second bonding structure 4250 are bonded may include copper (Cu).

In a semiconductor chip 2200a or a semiconductor device according to an embodiment, performance and integration of the semiconductor chip 2200a or the semiconductor device may be improved by a recess insulator 216 and/or a separation insulator 214 in the second transistor region A2.

Each of the semiconductor chips 2200a may further include an input/output pad 2210 and an input/output connection wiring 4265 at a lower portion of the input/output pad 2210. The input/output connection wiring 4265 may be electrically connected to a part of the second bonding structure 4250.

In an embodiment, in the semiconductor package 2003A, a plurality of semiconductor chips 2200 may be electrically connected to each other by the connection structure 2400 having a bonding wire type. In some embodiments, the plurality of semiconductor chips 2200 or a plurality of portions constituting the plurality of semiconductor chips 2200 may be electrically connected by a connection structure including a through silicon via (TSV).

While some examples have been described in connection with what is presently considered to be some practical embodiments, it is to be understood that the disclosure is not limited to the disclosed embodiments, and that that the disclosure is intended to cover various modifications and equivalent arrangements included within the spirit and scope of the appended claims.

What is claimed is:

1. A semiconductor device, comprising:
a semiconductor substrate including a first transistor region and a second transistor region;
a plurality of transistors including a first transistor in the first transistor region and a second transistor in the second transistor region having a larger operating voltage than the first transistor;
a plurality of isolation portions, each isolation portion disposed at a boundary of a respective transistor of the plurality of transistors at a first surface of the semiconductor substrate; and
a recess insulator disposed in the second transistor region at a second surface of the semiconductor substrate opposite to the first surface of the semiconductor substrate.

2. The semiconductor device of claim 1, further comprising:
a separation insulator connected to the recess insulator at a boundary of the second transistor in the second transistor region.

3. The semiconductor device of claim 2, wherein the separation insulator connects the isolation portion and the recess insulator in the second transistor region, and
the separation insulator has a width smaller than a width of the isolation portion.

4. The semiconductor device of claim 2, wherein a ratio of a width of the separation insulator to a width of the isolation portion is in the range of 1% to 10%.

5. The semiconductor device of claim 2, wherein a width of the separation insulator is smaller than a thickness of the semiconductor substrate in the second transistor region.

6. The semiconductor device of claim 2, wherein, in a cross-sectional view, the separation insulator includes an inclined side surface such that a width of the separation insulator gradually decreases from the first surface of the semiconductor substrate toward the second surface of the semiconductor substrate.

7. The semiconductor device of claim 2, wherein the second transistor includes a gate structure, a source region, and a drain region,
the plurality of transistors includes a plurality of high voltage transistors in the second transistor region including the second transistor, wherein each of the high voltage transistors has a larger operating voltage than the first transistor and are arranged in a transverse direction that is transverse to an extension direction of the gate structure, and
the separation insulator includes a portion extending in the extension direction at a boundary between adjacent high voltage transistors in the transverse direction.

8. The semiconductor device of claim 2, wherein the separation insulator is a first separation insulator and the semiconductor device further comprises a second separation insulator connected to the recess insulator at a boundary of the second transistor opposite the first separation insulator, and
in a cross-sectional view including the first and second separation insulators, a portion of the semiconductor substrate where the second transistor is positioned is separated from another portion of the semiconductor substrate by the first and second separation insulators and the recess insulator.

9. The semiconductor device of claim 1, wherein a thickness of the semiconductor substrate in the second transistor region is smaller than a thickness of the semiconductor substrate in the first transistor region.

10. The semiconductor device of claim 1, wherein the recess insulator is not positioned in the first transistor region and is positioned to span the entire second transistor region.

11. The semiconductor device of claim 1, wherein a silicon-on-insulator structure in which the semiconductor substrate is positioned on the recess insulator is provided in the second transistor region.

12. The semiconductor device of claim 1, wherein, in a cross-sectional view, the recess insulator includes an inclined side surface such that a width of the recess insulator gradually increases from the first surface of the semiconductor substrate toward the second surface of the semiconductor substrate.

13. The semiconductor device of claim 1, further comprising a plurality of low voltage transistors including the first transistor and a plurality of high voltage transistors including the second transistor, and
in a lateral direction, the semiconductor substrate includes a single portion to correspond to the plurality of low voltage transistors in the first transistor region and a plurality of portions in which each portion is separated from each other and corresponds to one of the high voltage transistors, respectively, in the second transistor region.

14. The semiconductor device of claim 1, wherein a thickness of the recess insulator is larger than a thickness of the semiconductor substrate in the second transistor region.

15. The semiconductor device of claim 1, wherein each of the first transistor and the second transistor has a planar structure, and
a thickness of a second gate insulation layer included in the second transistor is larger than a thickness of a first gate insulation layer included in the first transistor.

16. The semiconductor device of claim 1, comprising:
a circuit region including the semiconductor substrate and the plurality of transistors; and
a cell region positioned on the circuit region and including a memory cell structure.

17. An electronic system, comprising:
a main substrate;
a semiconductor device on the main substrate; and
a controller electrically connected to the semiconductor device on the main substrate,
wherein the semiconductor device includes:
a semiconductor substrate including a first transistor region and a second transistor region;
a plurality of transistors including a first transistor in the first transistor region and a second transistor in the second transistor region having larger operating voltage than the first transistor;
a plurality of isolation portions, each isolation portion disposed at a boundary of a respective transistor among the plurality of transistors at a first surface of the semiconductor substrate; and
a recess insulator disposed in the second transistor region at a second surface of the semiconductor substrate opposite to the first surface of the semiconductor substrate.

18. A method of manufacturing a semiconductor device, comprising:
forming an isolation portion at a first surface of a semiconductor substrate including a first transistor region and a second transistor region;
forming a first transistor in the first transistor region and a second transistor in the second transistor region; and
forming a recess insulator in the second transistor region at a second surface of the semiconductor substrate opposite to the first surface of the semiconductor substrate.

19. The manufacturing method of claim 18, further comprising:
forming a separation insulator corresponding to a boundary of the second transistor in the second transistor region at the first surface of the semiconductor substrate, before the forming of the recess insulator.

20. The manufacturing method of claim 19, wherein the forming of the recess insulator includes a process of forming a recess by etching a part of the semiconductor substrate in the second transistor region at the second surface of the semiconductor substrate, and a process of forming the recess insulator connected to the separation insulator by forming an insulating material in the recess.
